(19) United States
(12) Patent Application Publication
(10) Pub. No.: US 2026/0259674 A1
(43) Pub. Date: Sep. 3, 2026

(54) MEMORY BUILT-IN SELF-TEST WITH AUTOMATED DETECTION OF MAGNETIC TUNNELING JUNCTION DEGRADATION FOR REPAIR

(71) Applicant: Siemens Industry Software Inc., Plano, TX (US)

(72) Inventors: Jongsin Yun, Portland, OR (US); Martin Keim, Green Cove Springs, FL (US); Sina Bakhtavari Mamaghani, Karlsruhe (DE); Christopher Münch, Karlsruhe (DE); Mehdi Baradaran Tahoori, Karlsruhe (DE)

(73) Assignee: Siemens Industry Software Inc., Plano, TX (US)

(21) Appl. No.: 19/158,082

(22) PCT Filed: Apr. 14, 2023
(86) PCT No.: PCT/US2023/018666

§ 371 Date: Aug. 20, 2025

(51) Int. Cl. G06F 3/06

(52) U.S. Cl. CPC G06F 3/0653; G06F 3/0604; G06F 3/0655; G06F 3/0673

(57) ABSTRACT

This application discloses a memory device having multiple memory cells, each configured to store different values of data using different resistance states. A memory built-in self-test system can prompt the memory device to perform memory read operations for the memory cells storing the data in the different resistance states, determine a separation between the different resistance states of at least a subset of the memory cells, and detect one or more of the memory cells has a degraded tunneling layer in a magnetic tunneling junction based on the separation between the different resistive states in the at least the subset of the memory cells. A built-in repair analysis circuit can perform a repair of a group of the memory cells including at least on one of the detected memory cells based on the detection of the memory cells having degraded tunneling layers in the magnetic tunneling junctions.

### TECHNICAL FIELD

This application is generally related to electronic design automation and, more specifically, to memory built-in self-test with automated detection of magnetic tunneling junction degradation for repair.

### BACKGROUND

Magnetoresistive Random Access Memory (MRAM) has become an attractive non-volatile memory solution due to its small size, fast operation speed, and good endurance. MRAM devices can store data in magnetic domains, for example, as a spin polarity of magnets in their free layers. A MRAM device can write data in a magnetic domain by setting the spin polarity of magnets in its free layer, for example, providing a spin-polarized current through Magnetic Tunnel Junction (MTJ), which exerts torque on local magnetization in the free layer, often called Spin Torque Transfer (STT).

To read the stored data, the MRAM device can ascertain the spin polarity of the magnets in its free layer relative to a pinned reference layer underneath the corresponding free layer. When the spin polarity is parallel to the pinned reference layer, a resistivity on a reference bit-line (BL) of the MRAM device can be deemed low and thus correspond to a data “0” value. When the spin polarity is perpendicular or anti-parallel to the pinned reference layer, the resistivity on the reference bit-line of the MRAM device can be deemed high and thus correspond to a data “1” value. The MRAM device can include sensing circuitry to detect the resistivity on the reference bit-line of the MRAM device and compare the detected resistivity against a reference resistance to determine whether to deem the detected resistivity as low corresponding to a data “0” value or as high corresponding to a data “1” value.

Many MRAM devices have relatively small resistivity separation between a high resistive state associated with a data “1” value and a low resistive state associated with a data “0” value, which can render reliable data read operations a challenge. During the lifecycles of MRAM devices, a high current flowing through the magnetic tunnel junction during write operation can stress a tunneling layer and may introduce or expand interfacial defects between the free and pinned layers of the magnetic tunnel junction. Such defects can create trapped charges, which may reduce an activation energy for further tunneling layer bond distortion and limit the lifetime of MRAM devices. Although many of the MRAM devices having interfacial defects can be identified during manufacturing tests due to their reduced resistivity, some may still pass typical production testing with reduced resistivity separation. Some manufacturers can subject their MRAM devices to additional stress tests, for example, applying repeated stress to a MRAM memory cell using a hammer test. While these stress tests can further force degraded tunneling junctions to become defective, stress testing is often a costly process and impractical for high-volume production.

### SUMMARY

This application discloses a memory device having multiple memory cells, each configured to store different values of data using different resistance states. A memory built-in self-test system can prompt the memory device to perform memory read operations for the memory cells storing the data in the different resistance states, determine a separation between the different resistance states of at least a subset of the memory cells, and detect one or more of the memory cells has a degraded tunneling layer in a magnetic tunneling junction based on the separation between the different resistive states in the at least the subset of the memory cells. A built-in repair analysis circuit can perform a repair of a group of the memory cells including at least on one of the detected memory cells based on the detection of the memory cells having degraded tunneling layers in the magnetic tunneling junctions. Embodiments will be described below in greater detail.

### DESCRIPTION OF THE DRAWINGS

FIG. 1 illustrates an example memory system including a memory built-in self-test system with automated detection of magnetic tunneling junction degradation and repair analysis according to various embodiments.

FIG. 2 illustrates a graph of example read characteristics of a magnetoresistive memory device according to various embodiments.

FIG. 3 illustrates a flowchart showing an example automated detection of magnetic tunneling junction degradation and repair analysis according to various embodiments.

FIGS. 4A-4D illustrate graphs of showing an example implementation of an automated detection of magnetic tunneling junction degradation and repair analysis according to various embodiments.

FIG. 5 illustrates a table showing an example repair analysis based on detected memory cells having degraded magnetic tunneling junctions according to various embodiments.

### DETAILED DESCRIPTION

### Memory Built-In Self-Test With Automated Detection of Magnetic Tunneling Junction Degradation for Repair

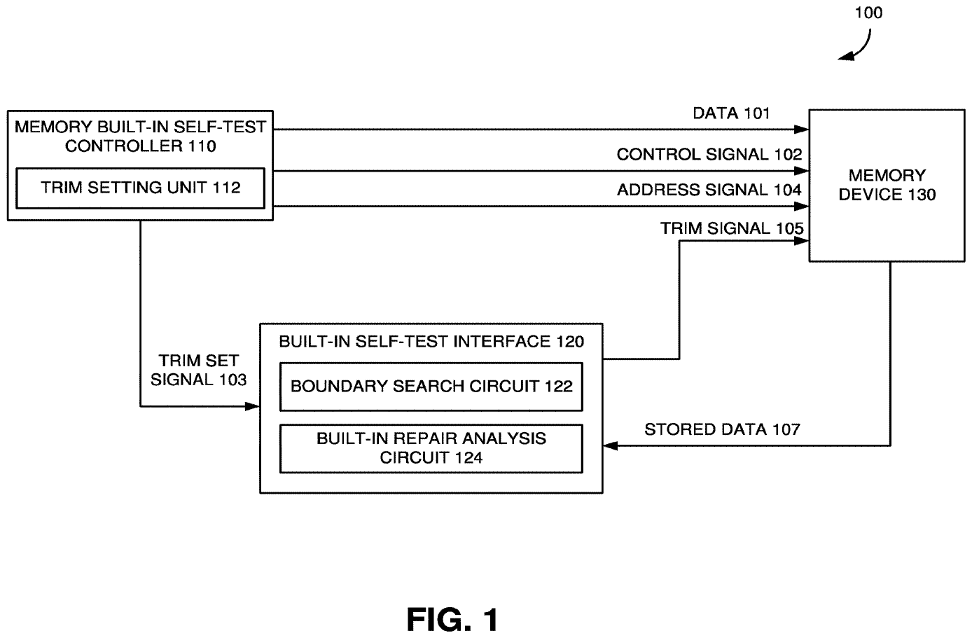

FIG. 1 illustrates an example memory system including a memory built-in self-test system with automated detection of magnetic tunneling junction degradation and repair analysis according to various embodiments. Referring to FIG. 1, the memory system 100 includes a memory device 130 to store data 101 during data write operations and to output stored data 107 during data read operations. In some embodiments, the memory device 130 can include a Magnetoresistive Random Access Memory (MRAM) to store the data 101 in magnetic domains, for example, as a spin polarity of magnets in a free layer. The Magnetoresistive Random Access Memory can be a Spin Torque Transfer (STT) MRAM device, which can write the data 101 by providing a spin-polarized current through Magnetic Tunnel Junction (MTJ), which exerts torque on local magnetization in the free layer. In other embodiments, the memory device 130 can include other types of Random Access Memory (RAM), such as Dynamic Random Access Memory (DRAM), Static Random Access Memory (SRAM), or the like, or include other types of non-volatile memory, such as Flash memory, Resistive Random Access Memory (ReRAM), or the like.

The memory system 100 can include a memory built-in self-test controller 110 to control memory access operations of the memory device 130. The memory built-in self-test controller 110 can generate a control signal 102 and an address signal 104 that, when provided to the memory device 130, can prompt the memory device 130 to perform a memory access operation, such as a data write operation or a data read operation at an address indicated by the address signal 104. When the control signal 102 corresponds to a data write operation, the memory device 130 can store the data 101 from the memory built-in self-test controller 110 at the address indicated by the address signal 104 in response to the control signal 102. When the control signal 102 corresponds to a data read operation, the memory device 130 can locate and output the stored data 107 at the address indicated by the address signal 104 in response to the control signal 102. The memory device 130 can read the stored data 107 by sensing an electric value, such as voltage, current, resistance, or the like, associated with a bit line of the memory device 130, and comparing the sensed electrical value against a reference value to determine whether the stored data 107 corresponding to a high data value associated with data “1” or a low data value associated with data “0”. In some embodiments, one or more intermediate data values between may exist between the high data value and the low data value.

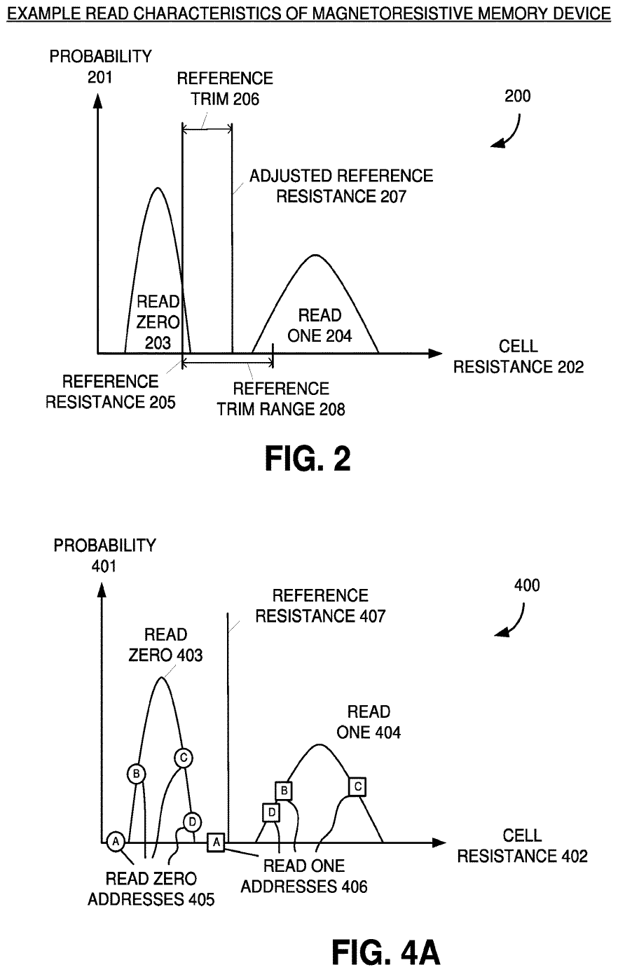

Since, in some instances, the reference value utilized by the memory device 130 to sense the data value of the stored data 107 can be misaligned with the electrical characteristics of one or more of the memory cells in the memory device 130, the memory device 130 can adjust the reference value with a reference trim, for example, provided to the memory device 130 in a trim signal 105. The memory device 130 can utilize the adjusted reference value to determine whether the stored data 107 corresponds to a high data value or a low data value. An example of read characteristics of a magnetoresistive memory device using a reference trim value is described below with reference to FIG. 2.

FIG. 2 illustrates a graph 200 of example read characteristics of a magnetoresistive memory device according to various embodiments. Referring to FIG. 2, the graph 200 has an x-axis corresponding to cell resistances 202 during read operations of the magnetoresistive memory device and has a y-axis corresponding to a probability 201 or likelihood of occurrence for each of the cell resistances 202. In this example, the read characteristics can include two groupings, one for cell resistances associated with reading a stored data “0” value or read zero 203 and another for cell resistances associated with reading a stored data “1” value or read one 204.

The magnetoresistive memory device also can include a reference resistance 205 value that can be utilized to determine whether a sensed cell resistance value corresponds to a data “0” value or a data “1” value stored in the magnetoresistive memory device. In the instant example, the reference resistance 205 sits within a range corresponding to cell resistances associated with the data “0” value or read zero 203, meaning the magnetoresistive memory device could sense a resistance of a stored data “0” value as stored data “1” value because the reference resistance 205 of the location of the reference resistance 205 in the read zero 203 grouping. In some instances, the magnetoresistive memory device can adjust the reference resistance 205 using a trim adjustment circuit to shift a reference resistance trim value or a reference trim 206 to generate an adjusted reference resistance 207, which can be located between the read zero 203 and the read one 204 characteristics of the magnetoresistive memory device.

Referring back to FIG. 1, the memory system 100 can include a built-in self-test interface 120 to generate the trim signal 105 having a value for the reference trim. In some embodiments, the value for the reference trim can correspond to a resistance value, a voltage value, a current value, or the like, to adjust a reference resistance, a reference voltage, a reference current, respectively. The built-in self-test interface 120 can provide the trim signal 105 to the memory device 130, which can utilize the value of the reference trim in the trim signal 105 to adjust the reference value used to read the stored data 107.

The built-in self-test interface 120 can automatically set the value for the reference trim that the memory device 130 can utilize to read the stored data 107. In some embodiments, the built-in self-test interface 120 can set the value of the reference trim using a read boundary search process, for example, by receiving known data values stored in the memory device 130 that were read with different values for the reference trim, determine a separation between different resistance states of memory cells in the memory device, and detect which of the memory cells, if any, have degraded tunneling layers in their magnetic tunneling junctions based on the separation between the different resistive states in the memory cells.

The memory built-in self-test controller 110 can include a trim setting unit 112 to initiate the read boundary search process, which allows the built-in self-test interface 120 to iteratively set values for the reference trim of the memory device 130. The trim setting unit 112 can write data 101 to the memory device 130, for example, by generating the control signal 102 and the address signal 104 to prompt the memory device 130 to perform data write operations with the data 101. In some embodiments, the trim setting unit 112 can write the same data value to memory cells in the memory device 130, such as a data “1” or a data “0”.

The trim setting unit 112 can generate a trim set signal 103 to prompt the built-in self-test interface 120 to select a value for the reference trim and provide the selected value to the memory device 130 in a trim signal 105. The trim setting unit 112 can prompt the memory device 130 to perform data read operations and output the stored data 107 using the value for the reference trim in the trim signal 105.

The built-in self-test interface 120 can include a boundary search circuit 122 to determine when the memory device 130 fails to output the stored data 107 with the same value as the data 101. In some embodiments, the boundary search circuit 122 can compare the stored data 107 read from the memory device 130 to a type of the test data, such as a data “1” value or a data “0” value, and detect failures by the memory device 130 to output the stored data 107 with the correct value based on the comparison. The boundary search circuit 122 can accumulate a number of the detected failures or an accumulated failure count and compare the accumulated failure count to a failure screen. In some embodiments, the failure screen can correspond to a threshold number of accumulated failures in the memory device 130 associated with a predefined threshold defect level for production.

In some embodiments, when the accumulated failure count falls above the failure screen value, the boundary search circuit 122 can iteratively select a new value for the trim signal 105 and prompt the memory device 130 to read the stored data 107 using the new value for the trim signal 105. The iterative process can continue until the boundary search circuit 122 locates a read boundary for the type of the data 101 stored in the memory device 130. For example, when the memory device 130 stored “0” data using a low resistive state in its memory cells, the boundary search circuit 122 can increment the value of the trim signal 105 until the accumulated failure count for a value of the trim signal 105 meets or falls below the value or criteria of the failure screen. Conversely, when the memory device 130 stored “1” data using a high resistive state in its memory cells, the boundary search circuit 122 can increment the value of the trim signal 105 higher until the accumulated failure count for a value of the trim signal 105 meets or falls above the failure screen. In other embodiments, the boundary search circuit 122 can iteratively select values for the trim signal 105 utilizing different search processes in order to identify when accumulated failure counts cross the failure screen and thus identify read boundaries for each type of the data stored by the memory device 130.

After locating the read boundary for each type of the data, the boundary search circuit 122 can record addresses of memory cells in the memory device 130 that corresponded to detected failures when the reference value used to read the stored data 107 was set to a resistance associated with each of the read boundaries. The boundary search circuit 122 can utilize the record memory addresses to identify which memory cells in the memory device 130 have a separation of resistive states indicative of a degraded tunneling layer in the magnetic tunneling junction of the memory cells. Embodiments of the read boundary search will be described below in greater detail.

The built-in self-test interface 120 can include a built-in repair analysis circuit 124 to perform repair operations for the detected memory cells in the memory device. In some embodiments, the built-in repair analysis circuit 124 can identify an error correction code (ECC) scheme implemented by the memory device 130, such as a 1-bit ECC, 2-bit ECC, or the like, per word of memory cells, and then utilize the ECC scheme, the detected memory cells, and other detected memory cell failures, such as stuck-at 0 or stuck-at 1 faults, to perform a repair analysis process on the rows of memory cells in the memory device 130. For example, when the memory device implements a 2-bit ECC, an error correction circuit implementing the ECC scheme can correct up to two memory cell failures per word of memory cells in the memory device 130. Even though the error correction circuit can correct up to two memory cell failures per word of memory cells in the memory device 130, the built-in repair analysis circuit 124 also can assign any row of memory cells in the memory device 130 having a combination of two or more memory cell failures or degraded memory cells a redundancy memory cell row for repair. The built-in repair analysis circuit 124 can utilize the repair assignments for the memory cell rows to set a redundant memory cells row in the memory device 130 to alleviate the memory cell failures and/or detected degradation. Embodiments of the repair analysis will be described below in greater detail.

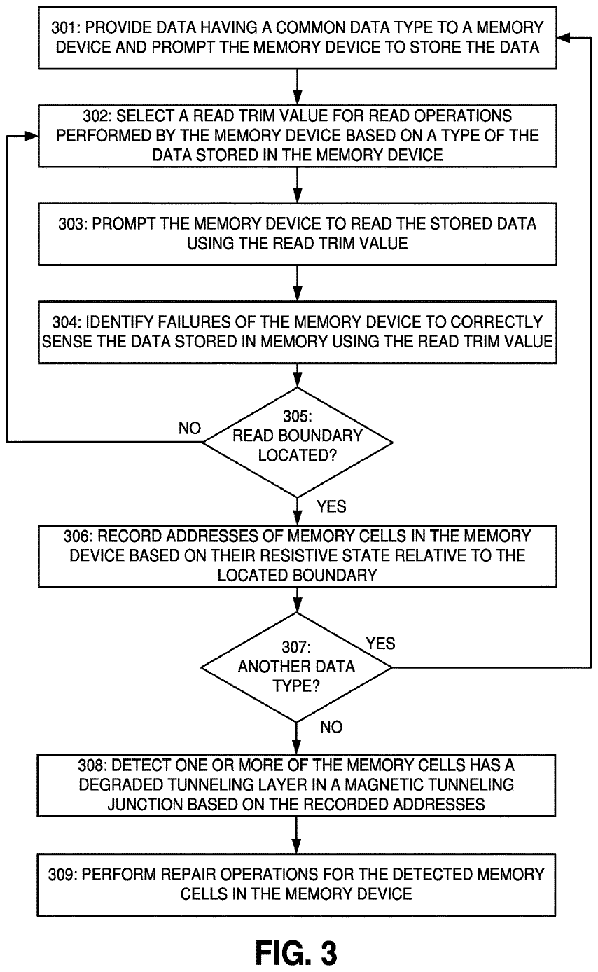

FIG. 3 illustrates a flowchart showing an example automated detection of magnetic tunneling junction degradation and repair analysis according to various embodiments. Referring to FIG. 3, in block 301, a memory built-in self-test system can provide data having a common data type to a memory device and prompt the memory device to store the data. The memory built-in self-test system can write the data to the memory device by generating a control signal to prompt the memory device to perform data write operations with the data. In some embodiments, the memory built-in self-test system can write the same data value to memory cells in the memory device, such as all data “1” values or all data “0” values.

In block 302, the memory built-in self-test system can select a read trim value for read operations performed by the memory device based on a type of the data stored in the memory device. In some embodiments, when the common data type corresponds to a “0” data value stored in memory cells of the memory device with a low resistive state, the memory built-in self-test system can initially select a read trim value having a highest allowable read trim value. When the common data type corresponds to a “1” data value stored in memory cells of the memory device with a high resistive state, the memory built-in self-test system can initially select a read trim value having a lowest allowable read trim value. In other embodiments, the memory built-in self-test system can initially select a different read trim value, for example, when implementing a different boundary search procedure, such as a binary search for the read boundaries.

In block 303, the memory built-in self-test system can prompt the memory device to read the stored data from memory using the read trim value. The memory built-in self-test system can generate a control signal to prompt the memory device to perform data read operations. In response to the control signal, the memory device can sense the stored data and compare the sensed data against a reference resistance to determine values for the stored data. In some embodiments, the reference resistance can correspond to an initial reference resistance of the memory device, which has been adjusted based on the road trim value.

In block 304, the memory built-in self-test system can identify failures of the memory device to correctly read the stored data using the read trim value and accumulate the identified failures into a failure count. The memory built-in self-test system can compare the data read from the memory device against the common data type of the stored data to determine whether the memory device correctly read the stored data using the read trim value. In some embodiment, the memory built-in self-test system can compare the data read from the memory device with expected data and report when there the comparison corresponds to a mismatch, which allows the memory built-in self-test system to count a number of the mismatches to determine the failure count of the memory device for the selected read trim value.

In block 305, the memory built-in self-test system can determine whether a read boundary for the common data type has been located. In some embodiments, the memory built-in self-test system can compare an accumulation of the identified failures of the memory device to a failure screen to determine whether the reference resistance associated with the selected read trim value corresponds to the read boundary for the common data type. The failure screen can correspond to a threshold number of accumulated failures in the memory device associated with a predefined defect level, and the read boundary can correspond to a resistance value where failures of the memory device to correctly read the common data type from memory device correlates to a transition across the failure screen.

When the memory built-in self-test system, in the block 305, determines that the read boundary has not been located, execution can return to the block 302, where the memory built-in self-test system can select another read trim value for read operations performed by the memory device based on a type of the data stored in the memory device and accumulated failure count relative to failure screen value. In some embodiments, when the common data type corresponds to a “0” data value stored in memory cells of the memory device with a low resistive state, the memory built-in self-test system can select a read trim value lower than the previously selected read trim value. When the common data type corresponds to a “1” data value stored in memory cells of the memory device with a high resistive state, the memory built-in self-test system can select a read trim value higher than the previously selected read trim value.

When the memory built-in self-test system, in the block 305, determines that the read boundary has not been located, execution can proceed to a block 306, where the memory built-in self-test system can record addresses of memory cells in the memory device that were identified as corresponding to failures during the read boundary test with the boundary trim setting and that correspond to memory cells having resistive states relative to the located read boundary. For example, when the common data type corresponds to a “0” data value stored in memory cells of the memory device with a low resistive state, the memory built-in self-test system can record addresses of memory cells having a low resistive state higher than the located read boundary. When the common data type corresponds to a “1” data value stored in memory cells of the memory device with a high resistive state, the memory built-in self-test system can record addresses of memory cells having a high resistive state lower than the located read boundary.

In a block 307, the memory built-in self-test system can determine whether to perform to perform a boundary search with additional data types. When another search is to be performed with at least one additional data type, execution can return to the block 301; otherwise execution can proceed to block 308. When execution returns to the block 301, the memory built-in self-test system can provide data having a different common data type to the memory device and prompt the memory device to store the data.

In the block 308, the memory built-in self-test system can detect one or more of the memory cells in the memory device has a degraded tunneling layer in a magnetic tunneling junction based on the recorded addresses. In some embodiments, the memory built-in self-test system can correlate the recorded addresses of the memory cells to a separation of a low resistive state and a high resistive state in the memory cells. When the memory built-in self-test system identifies a memory cell had its address recorded for multiple common data types, the memory built-in self-test system can deem the memory cell to have a lower tunneling magnetoresistance ratio (TMR), or ratio between the low resistive state and a high resistive state indicative of a tunneling layer degradation.

In a block 309, the memory built-in self-test system can perform repair operations for the detected memory cells in the memory device. In some embodiments, the memory built-in self-test system can identify an error correction code (ECC) scheme implemented by the memory device, such as a 1-bit ECC, 2-bit ECC, or the like, per row of memory cells, and then utilize the ECC scheme test, the detected memory cells, and other detected memory cell failures, such as stuck-at 0 or stuck-at 1 faults, to perform a repair analysis process on the rows of memory cells in the memory device. For example, when the memory device implements a 2-bit ECC, a single memory cell failure can utilize ECC to fix the failure, but any memory cell row in the memory device having a combination of two or more memory cell failures or degraded memory cells can be assigned for repair by an error correction circuit. The error correction circuit can utilize the repair assignments for the memory cell rows to set a redundant memory cells row in the memory device to alleviate the memory cell failures and/or detected degradation.

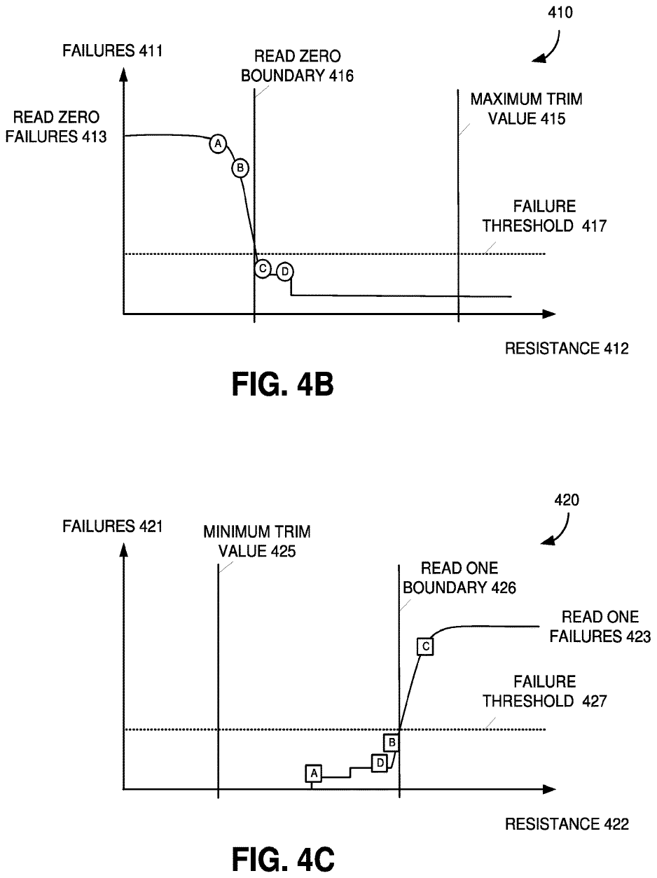

FIGS. 4A-4D illustrate graphs of showing an example implementation of an automated detection of magnetic tunneling junction degradation and repair analysis according to various embodiments. Referring to FIG. 4A, the graph 400 has an x-axis corresponding to cell resistances 402 during read operations of the magnetoresistive memory device and has a y-axis corresponding to a probability 401 or likelihood of occurrence for each of the bit line resistances 402. In this example, the read characteristics can include two groupings, one for cell resistances associated with reading a stored data “0” value or read zero 403 and another for bit line resistances associated with reading a stored data “1” value or read one 404. The magnetoresistive memory device also can include a reference resistance 407 value that can be utilized to determine whether a sensed bit line resistance value corresponds to a stored data “0” value or a stored data “1” value stored in the magnetoresistive memory device.

The graph 400 also includes specific read characteristics of four example memory cells A-D. The read zero 403 characteristics of the memory cells A-D can correspond to the read zero addresses 405, while the read one 404 characteristics of the memory cells A-D can correspond to the road one addresses 406. The cell resistance differences between the road zero addresses 405 and the read one addresses 406 corresponds to a separation between the resistive states of the memory cells A-D.

Referring to FIG. 4B, the graph 410 has an x-axis corresponding to reference resistances 412 used by magnetoresistive memory device during read operations and has a y-axis corresponding to accumulated failures 411 of read operations using the various reference resistances 412. The reference resistances 412 can range between a minimum trim value (not shown) and the maximum trim value 415, which correspond to a lowest value of the reference trim and a highest value of the reference trim, respectively. In this example, the graph 410 shows change of read zero failures 413 corresponding to a number of accumulated failures of the memory device to correctly read a data value of “0” under test at the various reference resistances. The read zero failures 413 show a high number of failures when the reference trim is closer to the minimum trim value, and a low number of failures when the reference trim is closer to the maximum trim value 415.

When performing a search for the read zero boundary 416 of memory cells in a memory device, a memory built-in self-test system can initially set the read trim value to an initial trim value based, at least in part, on a type of read boundary search being implement to locate the read zero boundary. In some embodiments, the memory built-in self-test system can initially set the read trim value based on a binary search procedure, for example, setting the trim value to a median value in a trim value range. In other embodiments, the memory built-in self-test system can initially set the read trim value to the maximum trim value 415. Regardless of the selected boundary search procedure, the memory built-in self-test system can utilize the selected read trim value to identify a number of read zero failures 413 with the read trim value, compare the read zero failures 413 to the failure threshold 417 or failure screen, and select a new value for the read trim. When the read zero failures 413 for a selected read trim value transition above the failure threshold 417, the memory built-in self-test system can determine that the read zero boundary 416 has been identified and record the address of the memory cells that failed with a higher resistance 412 in the search process. In this example, the four memory cells A-D have their read zero characteristics shown in graph 410. The memory cells A and B would not have their memory addresses recorded, as their read characteristics were below the read zero boundary 416, but the memory cells C and D would have their memory addresses recorded by the memory built-in self-test system.

Referring to FIG. 4C, the graph 420 has an x-axis corresponding to reference resistances 422 used by magnetoresistive memory device during read operations and has a y-axis corresponding to accumulated failures 421 of read operations using the various reference resistances 422. The reference resistances 422 can range between a minimum trim value 425 and the maximum trim value (not shown), which correspond to a lowest value of the reference trim and a highest value of the reference trim, respectively. In this example, the graph 420 shows read one failures 423 corresponding to a number of accumulated failures of the memory device to correctly read a data value of “1” using the various reference resistances. The read one failures 423 show a high number of failures when the reference trim is closer to the maximum trim value, and a low number of failures when the reference trim is closer to the minimum trim value 425.

When performing a search for the read one boundary 426 of memory cells in a memory device, a memory built-in self-test system can initially set the road trim value to an initial trim value based, at least in part, on a type of read boundary search being implement to locate the read zero boundary. In some embodiments, the memory built-in self-test system can initially set the read trim value based on a binary search procedure, for example, setting the trim value to a median value in a trim value range. In other embodiments, the memory built-in self-test system can initially set the read trim value to the minimum trim value 425. Regardless of the selected boundary search procedure, the memory built-in self-test system can utilize the selected read trim value to identify a number of read one failures 423 with the read trim value, compare the read one failures 423 to the failure threshold 427 or failure screen, and select a new value for the read trim. When the read one failures 423 for a selected read trim value transition above the failure threshold 427, the memory built-in self-test system can determine that the read one boundary 426 has been identified and record the address of the memory cells that failed with a lower resistance 422 in the search process. In this example, the four memory cells A-D have their read one characteristics shown in graph 420. The memory cell C would not have its memory addresses recorded, as its read characteristics was above the read one boundary 426, but the other memory cells A, B, and D would have their memory addresses recorded by the memory built-in self-test system.

Referring to FIG. 4D, the graph 430 has an x-axis corresponding to data zero resistance 432 of memory cells in a magnetoresistive memory device during read operations and has a y-axis corresponding to data one resistance 431 of memory cells in a magnetoresistive memory device during read operations. The data one resistance 431 can show a high resistive state used by the memory cells within the magnetoresistive memory device to store data values of “1”. When a memory cell has a high resistive state falling below a reference resistance level, such as memory cell A, the memory cell can correspond to a stuck-as zero failure 434 or hard failure of the memory cell. The data zero resistance 432 can show a low resistive state used by the memory cells within the magnetoresistive memory device to store data values of “0”. When a memory cell has a low resistive state falling above a reference resistance level, the memory cell can correspond to a stuck-as one failure 433 or hard failure of the memory cell.

The combination of the read one resistance 431 and the read zero resistance 432 for each memory cell can identify a tunneling magnetoresistance ratio (TMR) for memory cells. In this example, the four memory cells A-D shown in FIG. 4A have various combinations of the data one resistance 431 and the data zero resistance 432. The lower tunneling magnetoresistance ratio for the memory cell A corresponds to a failed memory cell 435 due to having a data one resistance 431 falling below the reference resistance, meaning it suffers from a stuck-at zero failure 434. The memory cells B and C do not correspond to hard failures and can be considered passed memory cells 437 due to having a higher tunneling magnetoresistance ratio. The memory cell D also does not correspond to a hard failure during read fail screen, but can be considered a degraded memory cell 436 due to having a lower tunneling magnetoresistance ratio. The lower tunneling magnetoresistance ratio for memory cell D can be indicative of having a degraded tunneling layer in its magnetic tunnel junction which has an elevated chance of having shorter lifetime and cause a field failure. In some embodiments, rather than using a TMR to identify degraded memory cells, a defect coverage can be increased by identifying the degraded memory cells through a performance of a read test with the reference trim set to the read one boundary 426. In this example, the memory cells A, B, and D can have their addresses marked as corresponding to degraded memory cells using this technique. While this technique can increase a defect coverage for the memory device, it may come at the cost of having to repair some memory cells that do not have a lower tunneling resistance, such as the memory cell B. In some other embodiments, an efficiency can be increased by identifying the degraded memory cells through a performance of a first read test with the reference trim set to the read one boundary 426 and a second read test with the reference trim set to the read zero boundary 416 based fail. In this example, the memory cell D can have its address marked as corresponding to degraded memory cell using this technique.

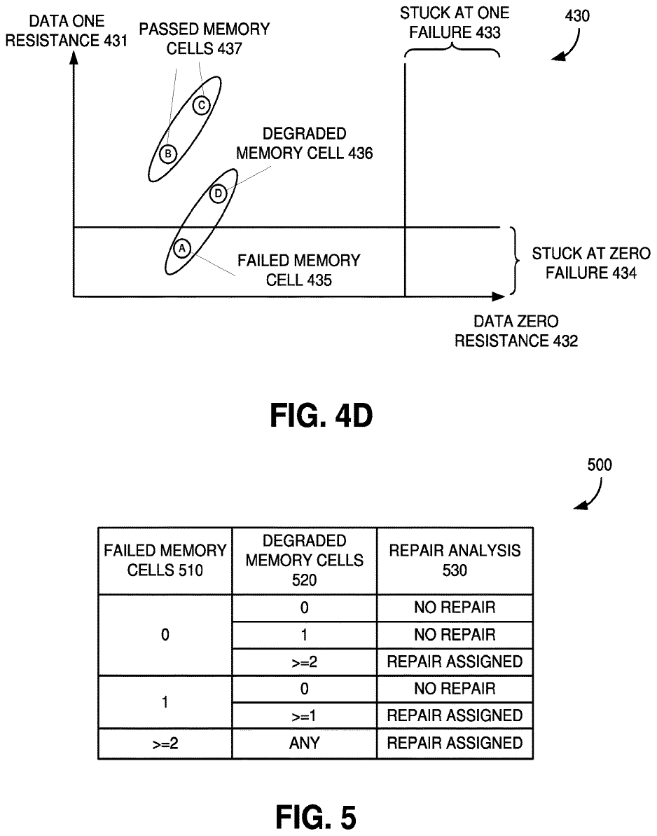

FIG. 5 illustrates a table 500 showing an example repair analysis based on detected memory cells having degraded magnetic tunneling junctions according to various embodiments. Referring to FIG. 5, the table 500 can correspond to a repair analysis performed on a memory device implementing a 2-bit an error correction code (ECC) scheme per row of memory cells. The table 500, in a row-column format, can include columns for failed memory cells 510, degraded memory cells 520, and a repair analysis 530. The failed memory cells 510 column can include various options for numbers of memory cells per row that were deemed hard or soft failures during manufacturing functional tests. The degraded memory cells 520 column can include various options for numbers of memory cells per row that were deemed to have degraded tunneling layers based on their low TMR value. The repair analysis 530 column can include an indication on when repair operations would be assigned to the memory cell row based on the combined numbers of failed memory cells 510 and degraded memory cells 520. In this example, when a memory cell row includes 2 or more hard failures, soft failures, or degraded memory cells per memory cell row, the table 500 would assign repair for that memory cell row; otherwise, the table 500 would not assign repair. As discussed above, the assignment of repair would be utilized by an error correction circuit to utilize a redundant memory cell row for the memory cell row assigned for repair, which will allow the memory device to avoid early field failure.

In some embodiments, the memory built-in self-test system can identify an error correction code (ECC) scheme implemented by the memory device, such as a 1-bit ECC, 2-bit ECC, or the like, per row of memory cells, and then utilize the ECC scheme, the detected memory cells, and other detected memory cell failures, such as stuck-at 0 or stuck-at 1 faults, to perform a repair analysis process on the rows of memory cells in the memory device. For example, when the memory device implements a 2-bit ECC, any memory cell row in the memory device having a combination of two or more memory cell failures or degraded memory cells can be assigned redundancy for repair instead of an error correction circuit. The error correction circuit test can utilize the repair assignments for the memory cell rows to set a redundant memory cells row in the memory device to alleviate the memory cell failures and/or detected degradation.

The system and apparatus described above may use dedicated processor systems, micro controllers, programmable logic devices, microprocessors, or any combination thereof, to perform some or all of the operations described herein. Some of the operations described above may be implemented in software and other operations may be implemented in hardware. Any of the operations, processes, and/or methods described herein may be performed by an apparatus, a device, and/or a system substantially similar to those as described herein and with reference to the illustrated figures.

The processing device may execute instructions or “code” stored in memory. The memory may store data as well. The processing device may include, but may not be limited to, an analog processor, a digital processor, a microprocessor, a multi-core processor, a processor array, a network processor, or the like. The processing device may be part of an integrated control system or system manager, or may be provided as a portable electronic device configured to interface with a networked system either locally or remotely via wireless transmission.

The processor memory may be integrated together with the processing device, for example RAM or FLASH memory disposed within an integrated circuit microprocessor or the like. In other examples, the memory may comprise an independent device, such as an external disk drive, a storage array, a portable FLASH key fob, or the like. The memory and processing device may be operatively coupled together, or in communication with each other, for example by an I/O port, a network connection, or the like, and the processing device may read a file stored on the memory. Associated memory may be “read only” by design (ROM) by virtue of permission settings, or not. Other examples of memory may include, but may not be limited to, WORM, EPROM, EEPROM, FLASH, or the like, which may be implemented in solid state semiconductor devices. Other memories may comprise moving parts, such as a known rotating disk drive. All such memories may be “machine-readable” and may be readable by a processing device.

Operating instructions or commands may be implemented or embodied in tangible forms of stored computer software (also known as “computer program” or “code”). Programs, or code, may be stored in a digital memory and may be read by the processing device. “Computer-readable storage medium” (or alternatively, “machine-readable storage medium”) may include all of the foregoing types of memory, as well as new technologies of the future, as long as the memory may be capable of storing digital information in the nature of a computer program or other data, at least temporarily, and as long at the stored information may be “read” by an appropriate processing device. The term “computer-readable” may not be limited to the historical usage of “computer” to imply a complete mainframe, mini-computer, desktop or even laptop computer. Rather, “computer-readable” may comprise storage medium that may be readable by a processor, a processing device, or any computing system. Such media may be any available media that may be locally and/or remotely accessible by a computer or a processor, and may include volatile and non-volatile media, and removable and non-removable media, or any combination thereof.

A program stored in a computer-readable storage medium may comprise a computer program product. For example, a storage medium may be used as a convenient means to store or transport a computer program. For the sake of convenience, the operations may be described as various interconnected or coupled functional blocks or diagrams. However, there may be cases where these functional blocks or diagrams may be equivalently aggregated into a single logic device, program or operation with unclear boundaries.

### CONCLUSION

While the application describes specific examples of carrying out embodiments of the invention, those skilled in the art will appreciate that there are numerous variations and permutations of the above described systems and techniques that fall within the spirit and scope of the invention as set forth in the appended claims. For example, while specific terminology has been employed above to refer to electronic design automation processes, it should be appreciated that various examples of the invention may be implemented using any desired combination of electronic design automation processes.

One of skill in the art will also recognize that the concepts taught herein can be tailored to a particular application in many other ways. In particular, those skilled in the art will recognize that the illustrated examples are but one of many alternative implementations that will become apparent upon reading this disclosure.

Although the specification may refer to “an”, “one”, “another”, or “some” example(s) in several locations, this does not necessarily mean that each such reference is to the same example(s), or that the feature only applies to a single example.

1. A system comprising:
a memory device having multiple memory cells, each configured to store different values of data using different resistance states;
a memory built-in self-test system configured to prompt the memory device to perform a plurality of memory read operations for the memory cells storing the data in the different resistance states, determine a separation between the different resistance states of at least a subset of the memory cells based, at least in part, on the memory read operations, and detect one or more of the memory cells has a degraded tunneling layer in a magnetic tunneling junction based on the separation between the different resistive states in the at least the subset of the memory cells.

2. The system of claim 1, further comprising a built-in repair analysis circuit to perform a repair of a group of the memory cells including at least on one of the detected memory cells based, at least in part, on the detection of the memory cells having degraded tunneling layers in the magnetic tunneling junctions.

3. The system of claim 2, wherein the memory built-in self-test system is configured to repair of the group of the memory cells by assigning a redundant group of memory cells in the memory device to store the data stored for the repaired group of the memory cells.

4. The system of claim 1, wherein the memory built-in self-test system is configured prompt the memory device to use different reference resistances when performing the memory read operations for the memory cells storing the data using a low resistive state, accumulate the failures of the memory cells to correctly sense the stored data, compare the accumulated failures to a threshold failure quantity to determine a low resistance failure boundary, and record a first set of the memory cells having low resistive states falling above the low resistance failure boundary.

5. The system of claim 4, wherein the memory built-in self-test system is configured prompt the memory device to use different reference resistances when performing the memory read operations for the memory cells storing the data using a high resistive state, accumulate the failures of the memory cells to correctly sense the stored data, compare the accumulated failures to the threshold failure quantity to determine a high resistance failure boundary, and record a second set of the memory cells having high resistive states falling below the high resistance failure boundary.

6. The system of claim 5, wherein memory built-in self-test system is configured to detect the one or more of the memory cells has the degraded tunneling layer in the magnetic tunneling junction as those memory cells having been recorded in both the first set of the memory cells and the second set of the memory cells.

7. The system of claim 1, wherein the magnetic tunneling junction includes the tunneling layer located between a fixed polarity layer and a switching polarity layer, and wherein a polarity of the switching polarity layer sets the memory cells in the different resistive states.

8. A method comprising:
sensing, by a memory device, values of data stored in memory cells using different resistance states during memory read operations;
determining, by a memory built-in self-test system, a separation between the different resistance states of at least a subset of the memory cells based, at least in part, on the memory read operations; and
detecting, by the memory built-in self-test system, one or more of the memory cells has a degraded tunneling layer in a magnetic tunneling junction based on the separation between the different resistive states in the at least the subset of the memory cells.

9. The method of claim 8, further comprising performing, by a built-in repair analysis circuit, a repair of a group of the memory cells including at least on one of the detected memory cells based, at least in part, on the detection of the memory cells having degraded tunneling layers in the magnetic tunneling junctions.

10. The method of claim 9, wherein performing the repair of the group of the memory cells further comprises assigning a redundant group of memory cells in the memory device to store the data stored for the repaired group of the memory cells.

11. The method of claim 8, further comprising:
prompting, by the memory built-in self-test system, the memory device to use different reference resistances when performing the memory read operations for the memory cells storing the data using a low resistive state;
accumulating, by the memory built-in self-test system, the failures of the memory cells to correctly sense the stored data, compare the accumulated failures to a threshold failure quantity to determine a low resistance failure boundary; and
recording, by the memory built-in self-test system, a first set of the memory cells having low resistive states falling above the low resistance failure boundary.

12. The method of claim 11, further comprising:
prompting, by the memory built-in self-test system, the memory device to use different reference resistances when performing the memory read operations for the memory cells storing the data using a high resistive state,
accumulating, by the memory built-in self-test system, the failures of the memory cells to correctly sense the stored data, compare the accumulated failures to the threshold failure quantity to determine a high resistance failure boundary, and
recording, by the memory built-in self-test system, a second set of the memory cells having high resistive states falling below the high resistance failure boundary.

13. The method of claim 12, wherein detecting the one or more of the memory cells has the degraded tunneling layer in the magnetic tunneling junction further comprises identifying those memory cells having been recorded in both the first set of the memory cells and the second set of the memory cells.

14. The method of claim 8, wherein the magnetic tunneling junction includes the tunneling layer located between a fixed polarity layer and a switching polarity layer, and wherein a polarity of the switching polarity layer sets the memory cells in the different resistive states.

15. An apparatus comprising:
a memory built-in self-test system configured to determine a separation between different resistance states used to store values of data in a plurality of memory cells, and detect one or more of the memory cells has a degraded tunneling layer in a magnetic tunneling junction based on the separation between the different resistive states; and
a built-in repair analysis circuit to perform repair operations on one or more memory cell rows that include the detected memory cells.

16. The apparatus of claim 15, wherein the built-in repair analysis circuit is configured to perform repair operations on the memory cell rows that by assigning redundant memory cell rows to store the data stored for the repaired memory cell rows.

17. The apparatus of claim 15, further comprising a memory device including the memory cells, each configured to store different values of data using the different resistance states.

18. The apparatus of claim 17, wherein the memory built-in self-test system is configured prompt the memory device to use different reference resistances when performing the memory read operations for the memory cells storing the data using a low resistive state, accumulate the failures of the memory cells to correctly sense the stored data, compare the accumulated failures to a threshold failure quantity to determine a low resistance failure boundary, and record a first set of the memory cells having low resistive states falling above the low resistance failure boundary.

19. The apparatus of claim 18, wherein the memory built-in self-test system is configured prompt the memory device to use different reference resistances when performing the memory read operations for the memory cells storing the data using a high resistive state, accumulate the failures of the memory cells to correctly sense the stored data, compare the accumulated failures to the threshold failure quantity to determine a high resistance failure boundary, and record a second set of the memory cells having high resistive states falling below the high resistance failure boundary.

20. The apparatus of claim 19, wherein memory built-in self-test system is configured to detect the one or more of the memory cells has the degraded tunneling layer in the magnetic tunneling junction as those memory cells having been recorded in both the first set of the memory cells and the second set of the memory cells.
